(19) United States
(12) Patent Application Publication
(10) Pub. No.: US 2002/0186590 A1
(43) Pub. Date: Dec. 12, 2002

(54) Nonvolatile semiconductor memory device having hierarchical sector structure

(75) Inventor: Seung-Keun Lee, Songnam-city (KR)

Correspondence Address: Steven M. Mills, MILLS & ONELLO LLP, Suite 605, Eleven Beacon Street, Boston, MA, 02108, US

(73) Assignee: Samsung Electronics Co., Ltd.

(21) Appl. No.: 10/058,652

(22) Filed: Jan. 28, 2002

(30) Foreign Application Priority Data
Jun. 11, 2001 (KR) 2001-32467

(51) Int. Cl. G11C 16/04

(52) U.S. Cl. 365/185.17

(57) ABSTRACT

Disclosed is a sector structure of a NOR type flash memory by which the layout area in a chip can be minimized thereby being used in a highly integrated semiconductor device. The structure includes a plurality of floating gate memory cells and a plurality of sectors for receiving a same matrix row select signal. Bit lines of each of the sectors connected to global bit lines so that the plurality of sectors may share a sense amplifier and a write driver.

### BACKGROUND OF THE INVENTION

1. Field of the Invention

The present invention relates to an electrically erasable and programmable nonvolatile semiconductor memory device, and more particularly, to a nonvolatile semiconductor memory device having the hierarchical sector structure appropriate to high integration.

2. Description of the Related Art

Semiconductor memory devices can generally be classified into volatile and nonvolatile semiconductor memory devices. The volatile semiconductor memory device is further classified into dynamic random access memory (DRAM) and static random access memory (SRAM). The volatile memory device as such performs quick read and write operations, but it has a disadvantage in losing the contents stored at memory cells if external power stops being supplied. On the other hand, the nonvolatile semiconductor memory device is further classified into a mask read only memory (MROM), programmable read only memory (PROM) and electrically erasable and programmable read only memory (EEPROM).

Since the aforementioned types of nonvolatile semiconductor memory device can permanently store the contents contained in the memory cells even if external power is interrupted, they are mainly used for storing all the contents to be stored regardless of power supply. However, in the case of MROM, PROM or EEPROM, common users are not free to perform erase and write (or program) processes. In other words, it is not convenient to erase or re-program the contents programmed at the on-board state. On the other hand, it is possible for the EEPROM system to perform the electrical erase and write processes. Therefore, the EEPROM has been continuously expanded in applications to be used as a system program storage device or an auxiliary memory device requiring continuous renewal of its contents.

It would be beneficial to have an EEPROM that can be electrically erasable or programmable at high speed for a variety of electronic devices that can be controlled by computers or microprocessors. Furthermore, since a relatively large area is taken for a hard disc device having a rotary magnetic disc to be used as an auxiliary memory device in a battery powered computer system at the size of a portable computer or notebook computer, designers of such systems have been greatly interested in development of an EEPROM having compact size and high-speed operation.

Accordingly, a NOR type flash EEPROM having a flash erase function, which appeared along with the advancement of EEPROM design technology, has been welcomed by users who have demanded a high speed memory device including faster program, write and read operations than those of NAND type or AND type EEPROM. General operations of the NOR type flash memory device will now be described by way of background.

A memory cell transistor constructing a memory cell unit of a general NOR type flash memory has a structure with a vertical cross-section as shown in FIG. 5. In FIG. 5, an n-type source region 12 is formed on a p-type substrate 10, and an n-type drain region 14 is formed apart from the source region 12 with a p-type channel region between the source region 12 and the drain region 14. A floating gate electrode 16 insulated with a thin insulating layer of less than 100 angstroms on the p-type channel region is formed, and a control gate 18 is made by inserting another insulating layer over the floating gate electrode 16. The drain region 14 is connected to bit lines and the source region 12 is connected to source line. Since the control gate 18 electrode is formed of a word line made of poly-silicon, a portion of the word line region corresponding to the size of the floating gate 16 operates as an electrode of the control gate 18.

Next, the operation of the memory cell transistor having the structure shown in FIG. 5 will be described with reference to FIG. 6 that includes levels of voltage to be applied depending on respective operational modes classified into program, erase, erase repair and read modes.

The program operation is performed by injection of hot electrons from the drain region 14 and its adjacent channel region into the floating gate electrode 16. As shown in FIG. 6, the injection of hot electrons is made by applying a high level of voltage, 9V for instance, to the control gate electrode 18, and an adequate level of voltage, 5V for instance, to the drain region 14 for generation of hot electrons, at a state that the source region 12 and the p-type substrate region 10 are grounded.

When negative charges are sufficiently accumulated at the floating gate electrode 16 by the aforementioned method, the memory cell transistor has a higher level of threshold voltage than that prior to the program operation. On the other hand, the read operation is performed by applying a level of positive voltage, 1V for instance, to the drain region 14 and a predetermined level of voltage, 4.5V for instance, to the control gate electrode 18 while the source region 12 and the substrate region 10 are grounded. At that time, the amount of electric current flowing through the memory cell transistor is sensed by a sense amplifier. In the read operation, the memory cell transistor having a threshold voltage increased during the program operation operates as an off-cell to keep current from flowing from the drain region 14 to the source region 12. At this time, the programmed memory cell transistors generally have a level of threshold voltage in the range of 6-7V.

In the NOR type flash memory cell transistor, the erase operation is performed by generation of a Fowler-Nordheim tunneling phenomenon (hereinafter referred to as F-N tunneling) from a bulk region 10 formed at the substrate to the control gate electrode 18. For the generation of the F-N tunneling, it is required that a high level of negative voltage, −9V for instance, be applied to the control gate electrode 18 and an adequate level of voltage, 9V for instance, to the bulk region 10, as shown in FIG. 6. In this case, the drain region 14 and source region 12 are set at a high level of impedance to increase an effect of the erase operation. The aforementioned conditions of the erase operation form a strong electric field between the control gate electrode 18 and the bulk region 10 to bring about the F-N tunneling. Accordingly, the negative charges contained at the floating gate electrode 16 are discharged to the source region 12. The F-N tunneling is commonly known to happen when the electric field of 6-7MV/cm is applied to the conductive layer between the insulating layers. In the aforementioned memory cell transistor, it is understood that the gate insulating layer is formed to a thickness of 100 angstroms to thereby allow the generation of the F-N tunneling. As a result of the erase operation, the threshold voltage gets lower at the memory cell transistor than that of the case when electric charges are accumulated at the floating gate electrode 6.

In the general flash memory, a plurality of cells are formed at respective bulk regions for highly integrated memory, so that the plurality of cells are simultaneously erased during the aforementioned erase operation. An erase unit is determined according to the state that respective bulk regions are divided. For instance, an erase operation can be performed by 64K bytes, referred to as a sector. That is, the sector indicates a unit array of the memory cells that are erased at one time.

During performance of the read operation according to the voltage application conditions shown in FIG. 6, the memory cell having the level of threshold voltage lowered by the erase operation operates as an on-cell because of a current path from a drain region to a source region. At this time, the memory cell transistor is called an on-cell. The threshold voltage of the erased memory cell transistors is in the range of about 1V-3V. However, when the erase operation is performed by which the threshold voltage of the memory cell transistors is lowered, the level of threshold voltage maybe reduced to less than 0V, out of the range of 1V-3V, due to the uniformity at a plurality of memory cell transistors. Those memory cell transistors having a level of threshold voltage less than 0V are referred to as over-erased cells, which require curing operations (hereinafter referred to as erase-repair operations) to raise the level of threshold voltage to the range of about 1V-3V. The erase-repair operations can be achieved by grounding the source region 12 of the over-erased memory cell transistors and the bulk region 10, applying a level of positive voltage, 2V-5V for instance, to the control gate electrode 8 and applying a level of positive voltage, 6V-9V for instance, to the drain region 14. As a result of the erase-repair operations, an amount of negative charge, less than that of the program operation, is accumulated at the floating gate electrode 16 to the threshold voltage range of about 1V-3V.

FIG. 1 illustrates the case in which memory cell transistors performing the program, read, and erase operations are arranged every sector in a chip. Referring to FIG. 1, each of the sectors has a hierarchical sector structure along the word line direction. The hierarchical sector structure is conveniently used in reducing the number of row decoders for coding word lines W/L, as described in the following. Reference numerals 101, 201, 301, 401 indicate sector cell arrays each of which is formed of a plurality of memory cells. The word line W/L and the bit line B/L in each of the sector cell arrays are connected to a plurality of memory cells, respectively. Reference numerals 102, 202, 302, 402 indicate circuits for selecting bit lines of the corresponding sector cell arrays and are commonly called a Y pass gate circuit. Reference numeral 100 indicates one sector including the row decoders 21, 31 for selecting the Y pass gate circuit 102, the sector cell array 101, and the word line W/L. By the sector 100 structure, the sector cell array 101, the word line W/L, and bit line B/L are selected and a series of program/erase/read operations are accordingly performed. Similarly, the other sectors 200, 300, 400 have the same internal structure.

Referring to FIG. 1, the sectors 100 and 200 arranged in a word line direction, i.e., in a row direction, are connected to a same global word line W/L. Accordingly, the signals GWL0-GWLn of the global word line GWL, which are input to the row decoders 21, 22, 31, 32 of the sectors 100, 200, serve to enable the W/L of the sectors 100, 200. That is, one GWL signal is a signal for selecting one row decoder from each of the sectors. The row decoders 21, 22, 31, 32 in each of the sectors receive a sector row select signal through the global word line to enable the corresponding word lines W/L. For example, in order that the sector 100 is selected, the select signal MATX0 in a row direction of the sectors is enabled and the X-address is input to the global row decoders 2, 4. The global row decoders 2, 4 serve to activate one signal out of the global word line signals GWL0-GWLn. On the other hand, if the select signal MATY0 of the sector Y direction is input to the row decoders 21, 31 in the sector 100, one row decoder is selected from the row decoders to thereby activate the corresponding one of the W/Ls.

In the same manner, the column decoder I (6) receives the column address (Y-address) and the matrix row select signal MATX0 to drive the Y-pass gate circuit 102, thereby the pass transistor selected in the Y-pass gate circuit 102 is enabled. In addition, the selected bit line B/L is electrically connected to the data line D/L that is connected to the sense amplifier 12 and the write driver 14, thereby data in the selected memory cell is programmed or data in the memory cell is read. Accordingly, since the sector cell arrays 101, 201 employing same matrix row select signal MATX0 have paths through which data are read or programmed with the same data line D/L, the sense amplifier 12 and the write driver 14 are commonly used in the plurality of sectors that are arranged in a row direction and share a same global word line.

In the same manner as described above, the read/program operations can be performed even in the other sectors 300, 400 employing other matrix row select signals MATXi.

The bit line B/L connected to the drain of the memory cell transistor as shown in FIG. 1 is formed of metal 1, the W/L, which can operate as a control gate of the memory cell, is formed of poly-silicon, and the global GWL can be formed of metal 2 that is formed on the metal 1.

As described in the foregoing, according to the conventional techniques having the hierarchical structure along the word line direction, since the number of sectors should increase as the degree of the integration of memory chip increases, the number of the matrix row select signal MATXi accordingly increases. In this case, since the sense amplifier and write driver should be added whenever each of the matrix row select signals MATXi is added, the layout area of a chip increases, thereby increasing chip size and limiting improvement in high integration of the chip.

### SUMMARY OF THE INVENTION

It is an object of the present invention to solve the aforementioned problems and provide a method for reducing or minimizing the layout area of a nonvolatile semiconductor device.

It is another object of the present invention to provide an improved column decoding method by which the layout area of a chip in a NOR type nonvolatile semiconductor device can be reduced.

It is still another object of the present invention to provide a semiconductor memory device having the hierarchical sector structure that is convenient for high integration.

It is yet another object of the present invention to provide a NOR type flash memory device having the hierarchical sector structure along a bit line direction as well as the hierarchical sector structure along a word line direction.

It is further another object of the present invention to provide a nonvolatile semiconductor device by which the number of sense amplifiers and write drivers can be reduced or minimized.

It is another object of the present invention to provide a nonvolatile semiconductor memory device having the sector structure by which chip area can be reduced when high integration of the chip is realized.

In accordance with an aspect of the present invention, there is provided a NOR type flash memory device. The device includes a plurality of floating gate memory cells for performing an erase operation by sector unit. A plurality of sectors receive a same matrix row select signal, bit lines of each of the sectors being connected to global bit lines so that the plurality of sectors share a sense amplifier and a write driver.

In accordance with another aspect of the present invention, there is provided another NOR type flash memory device. The device includes a plurality of floating gate memory cells for performing an erase operation by sector unit. A plurality of sectors receive matrix row select signals that are different from one another in a column direction and matrix column select signals that are different from one another in a row direction. Word lines of each of the sectors are connected to global word lines, and bit lines of each of the sectors are connected to global bit lines so that the plurality of sectors may share a sense amplifier and a write driver, the sectors being arranged in a matrix.

In accordance with another aspect of the present invention, there is provided a column decoding method of a NOR type flash memory device having a plurality of floating gate memory cells for performing an erase operation by sector unit. According to the method, a local column decoding operation and a global column decoding operation are performed to hierarchically select bit lines at a state that a plurality of sectors for receiving a same matrix row select signal in each of which bit lines are connected to global bit lines so that the plurality of sectors may share a sense amplifier and a write driver.

### BRIEF DESCRIPTION OF THE DRAWINGS

The foregoing and other objects, features and advantages of the invention will be apparent from the more particular description of a preferred embodiment of the invention, as illustrated in the accompanying drawings in which like reference characters refer to the same parts throughout the different views. The drawings are not necessarily to scale, emphasis instead being placed upon illustrating the principles of the invention.

FIG. 1 is a block diagram illustrating the sector structure of a NOR type flash memory according to the prior art.

FIG. 2 is a block diagram illustrating the sector structure of a NOR type flash memory having a hierarchical sector structure in a bit-line direction in accordance with an embodiment of the present invention.

FIG. 3 is a detailed view illustrating the sector structure in one sector shown in FIG. 2.

FIG. 4 is a view illustrating the layout structure of the memory chip shown in FIG. 2.

FIG. 5 is a cross sectional view of a common NOR type memory cell transistor.

FIG. 6 is a table showing the applied voltages versus operation modes necessary in driving the transistor shown in FIG. 5.

### DETAILED DESCRIPTION OF PREFERRED EMBODIMENTS

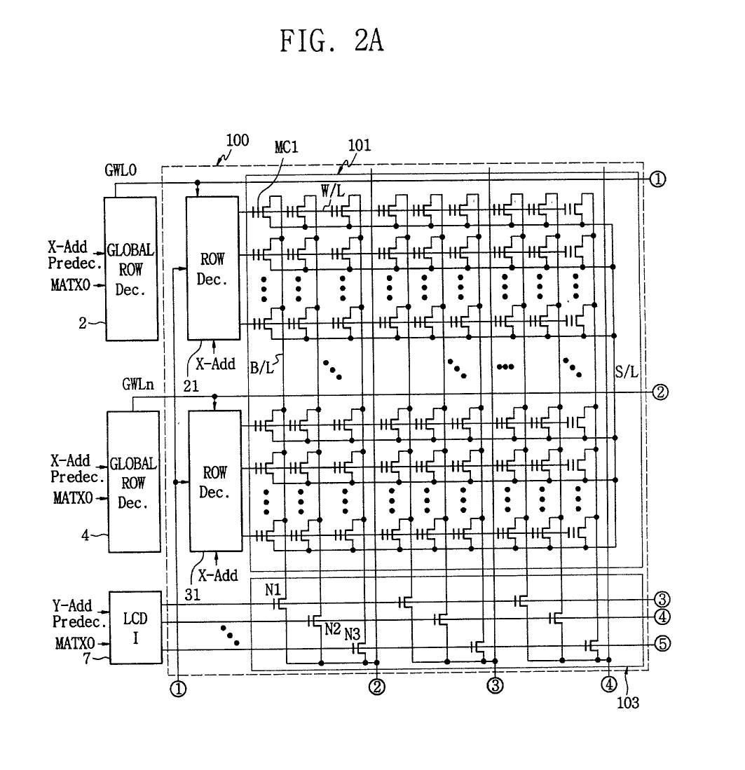

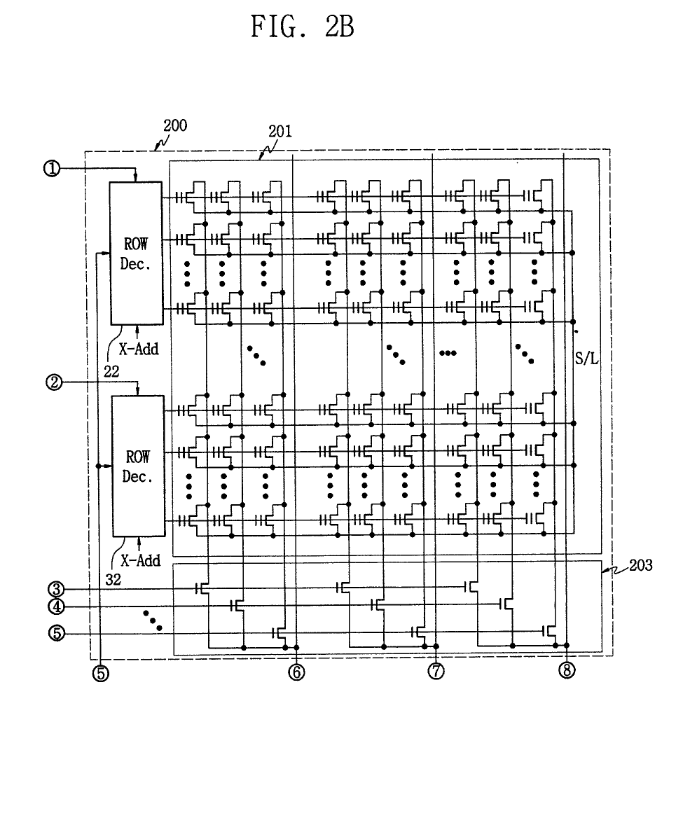

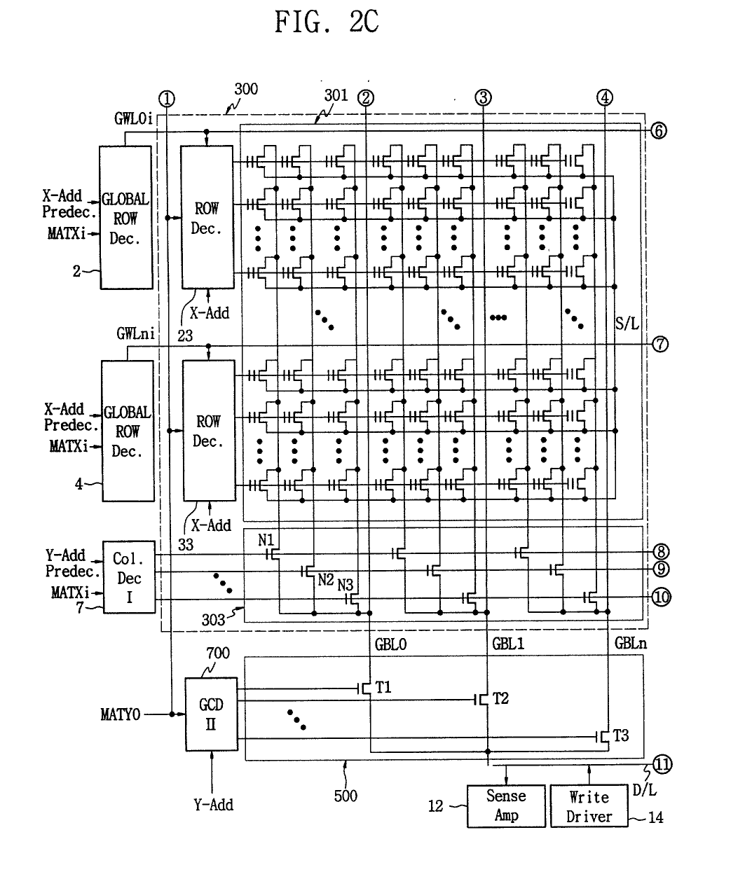

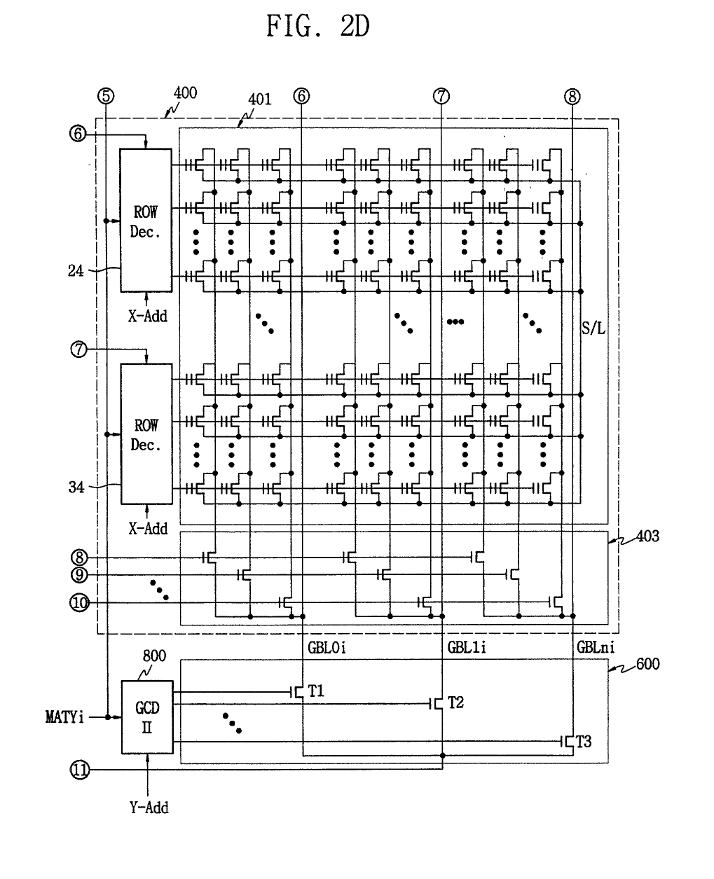

Referring to FIG. 2 showing the sector structure of one embodiment of a NOR type flash memory according to the present invention, the sectors 100, 200, 300, 400 comprises row decoders 21-24, 31-34 for driving word lines of each of the sectors, sector cell arrays 101, 201, 301, 401 formed of a plurality of memory cell transistors connected to a plurality of word lines and bit lines, and Y-pass gate circuits 103, 203, 303, 403 selecting one of the bit lines in response to local column decoding signal.

The row decoders 21, 22 and row decoders 31, 32 are respectively connected to the global word lines GWL0, GWLn that are output lines of the global row decoder 2 and global row decoder 4. The row decoders 23, 24 and row decoders 33, 34 are connected to the global word lines GWL0i, GWLni that are output lines of the global row decoder 2 and global row decoder 4. The Y-pass gate circuits 103, 203, 303, 403 are connected to corresponding to the sector cell arrays 101, 201, 301, 401. The local column decoders (LCD) 7 which output a local column decoding signal are connected to the Y-pass gate circuits 103, 203 and the Y-pass gate circuits 303, 403, respectively. The global column decoders (GCD) 700, 800 are connected to the global column pass gates 500, 600, respectively. The sense amplifier 12 and the write driver 14 are commonly connected to the output line of the global column pass gates 500, 600.

In the drawing, the plurality of word lines are connected to the corresponding global word lines, and the plurality of bit lines are connected to the global bit lines. Each of the word lines W/L is commonly connected to control gates of n memory cells. Each of the bit lines B/L is commonly connected to drains of m memory cells. Accordingly, the m bit lines are connected to a common data line D/L via the Y-pass gate circuits 103, 203, 303, 403 and the global column pass gates 500, 600 and the common data line D/L is connected to a sense amplifier 12 and a write driver 14.

As described above, the main feature of the structure as shown in FIG. 2 is that the sectors 100, 300 and the sectors 200, 400 each have the hierarchical structure in a B/L direction in addition to the structure in which the sectors 100, 200 and the sectors 300, 400 each have the hierarchical structure in a W/L direction. By the hierarchical structure, each of the word lines and the bit lines are hierarchically selected in a word line direction as well as a bit line direction.

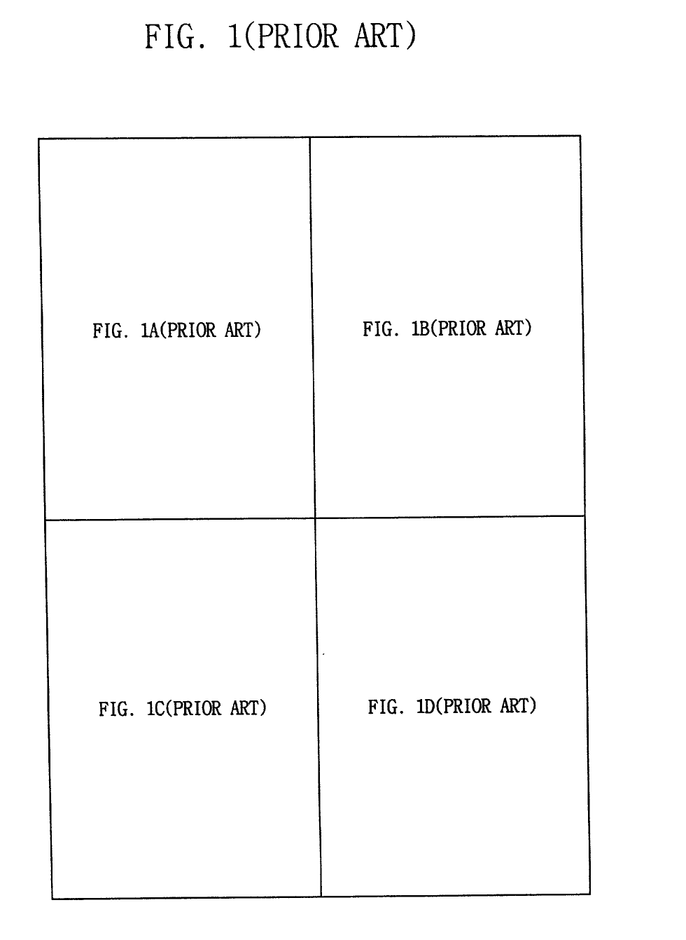

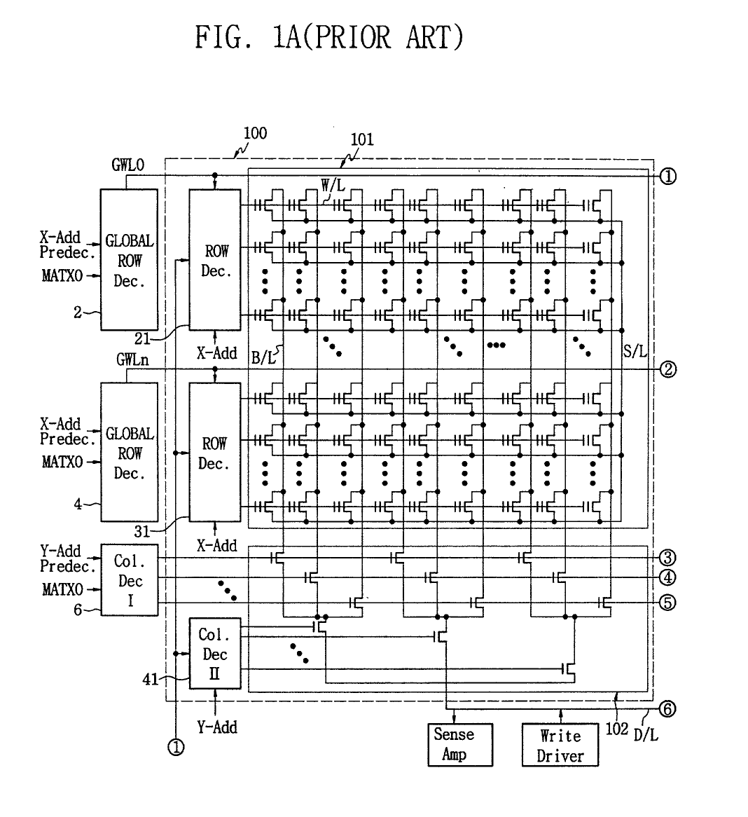

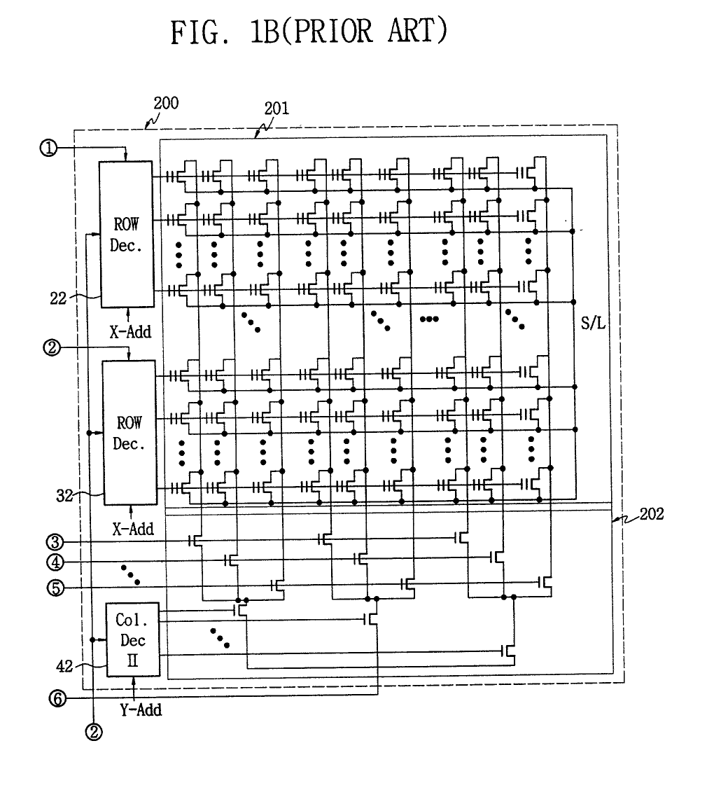

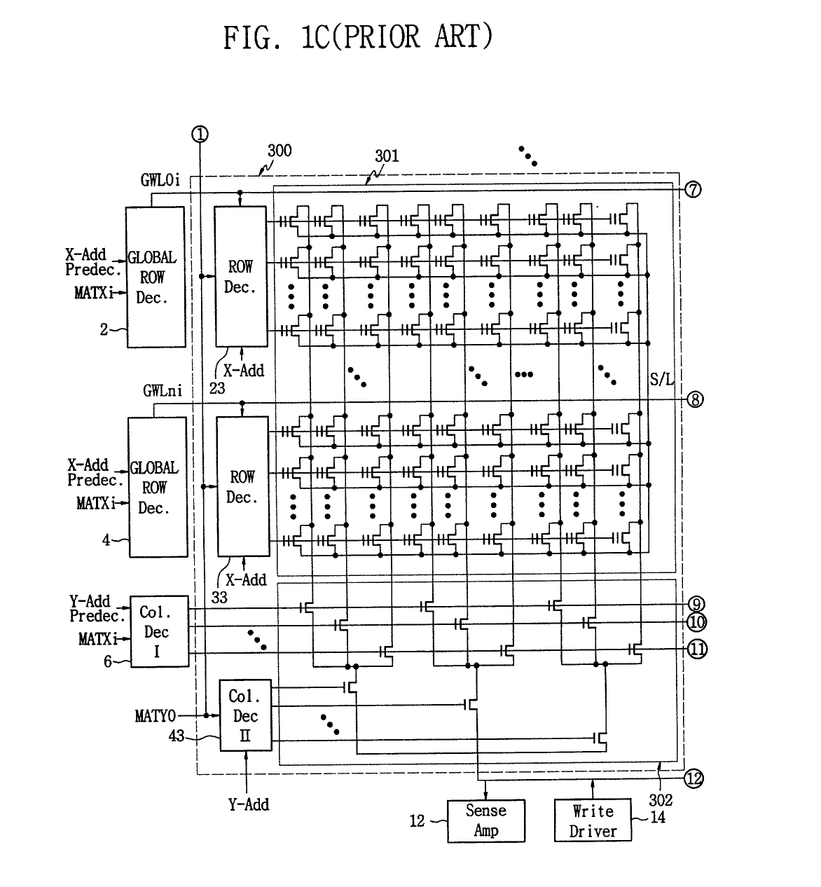

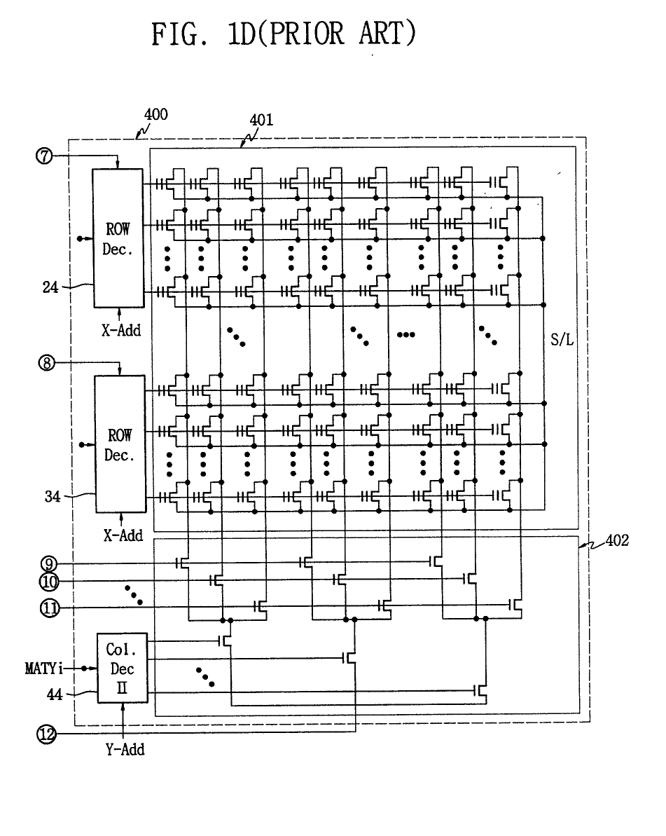

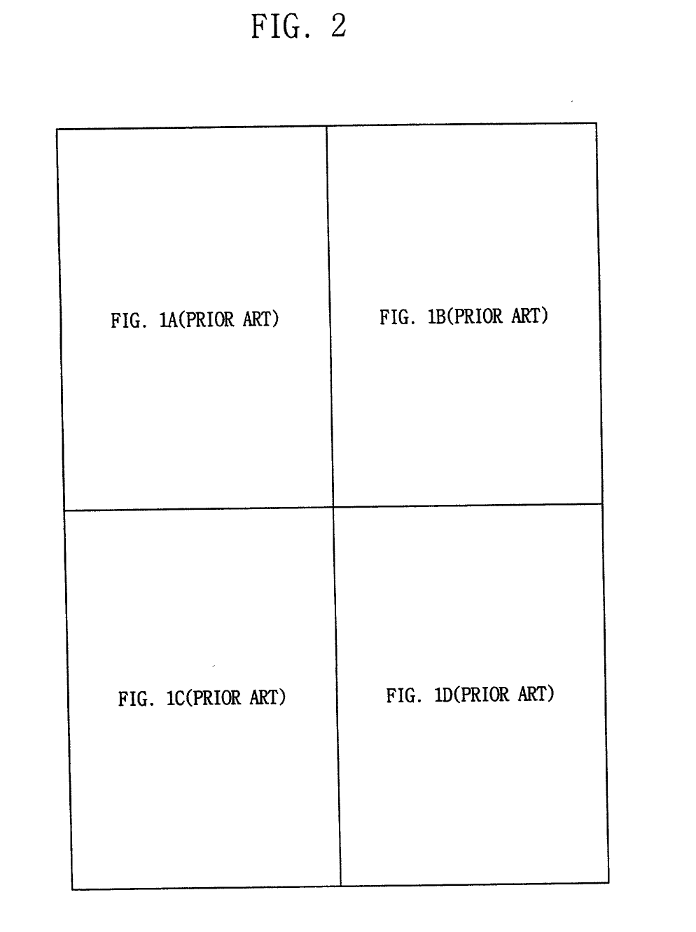

According to the structure as described above, since the sense amplifier 12 and the write driver 14 are commonly used in the plurality of sectors that receive matrix row select signals different from each other, the layout area in a chip can be reduced compared with the structure shown in FIG. 1. In addition, even in the case that the number of the sectors should increase for a high integration in a chip, the sense amplifier and the write driver do not need to be added, thereby lessening a burden to the layout area. In other words, the problem of increasing chip size can be overcome.

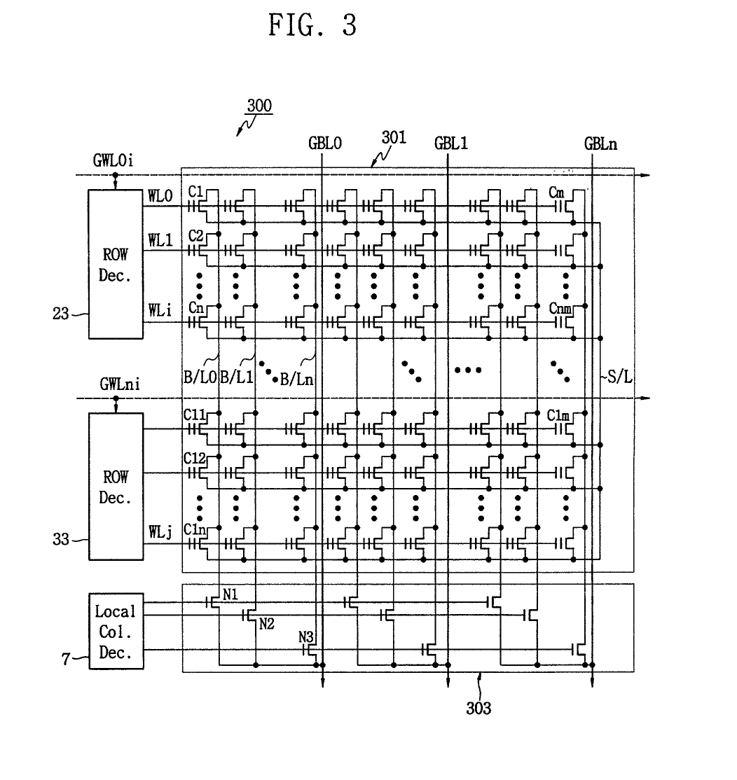

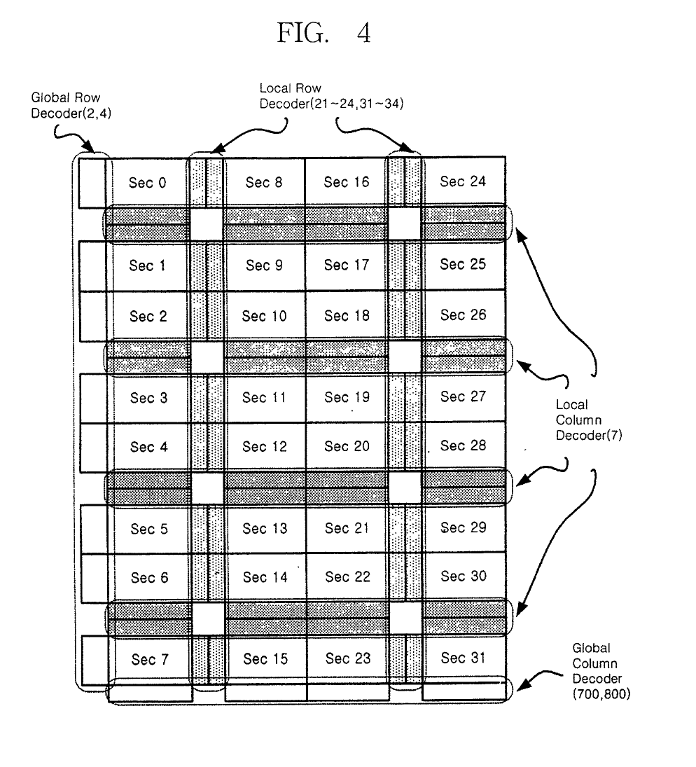

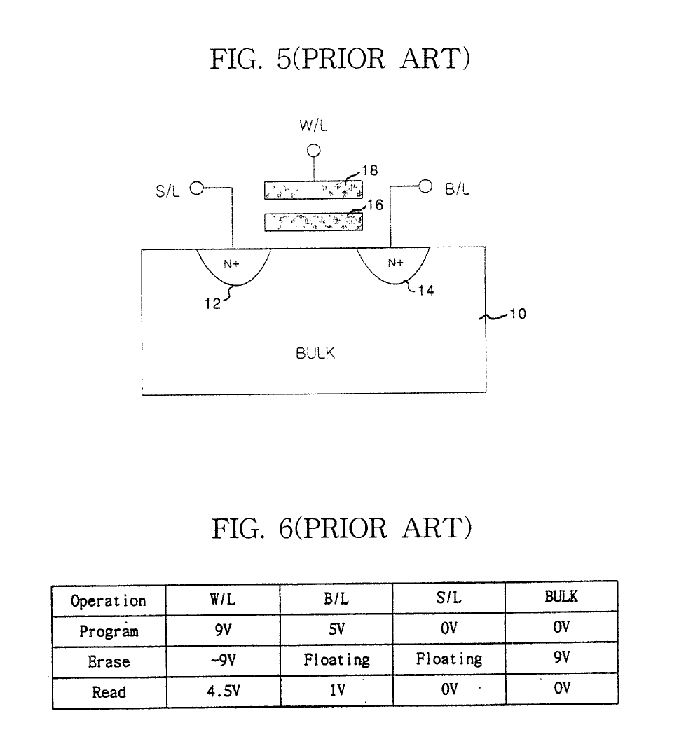

FIG. 3 is a detailed view showing the sector 300 shown in FIG. 2. The word lines WL0-WLi that are arranged in the sector array 301 in a row direction are formed of poly-silicon. The bit lines B/L0-B/Ln that are vertically crossed are formed of metal 1 through a first metal deposition process. The global WL, which is a high level of word line W/L, can be formed of metal 2, which is a second metal layer. The global BL, which is a high level of bit line B/L, can be formed of metal 3, which is a third metal layer. In such a manner, the metal 2 and the metal 3 are arranged in a W/L direction and a B/L direction, respectively, over the memory cell forming the sector cell array 301. Here, the metal 2 and the metal 3 may alternatively be arranged in a B/L direction and a W/L direction, respectively, unlike the structure shown in the drawing.

FIG. 4 is a view showing the chip layout structure of a chip shown in FIG. 2. Referring to FIG. 4, it is shown that 32 sectors are arranged. The global decoders 2, 4 generating a GWL that is a global W/L signal are arranged on the left side in the drawing. The local row decoders 21-24, 31-34 are arranged in the sector cell array parallel to the global row decoders 2, 4. The local column decoder 7 is arranged perpendicular to the local row decoder. The global column decoders 700, 800 are arranged in a low portion in the drawing.

Now, the data access operation according to the structure shown in FIG. 2 will be described below. The erase operation is performed by a sector unit. The erase by a sector unit means that the memory cell transistors formed in a same bulk region are erased at a time. One sector may include memory cell transistors of 64 K byte.

The process in which the word line W/L connected to a memory cell MC1 in a sector 100 is selected is as follows.

First, one of the GWL0-GWLn is activated by the global row decoders 2, 4 receiving the matrix row select signal MATX0 and the row pre-decoding address or the row address X-address. When the matrix row select signal MATY0 is applied to the row decoders 21, 31, one of the row decoders 21 is selected. The row decoder 21 activates one of the W/L in response to a row address. The operation for activating one word line in FIG. 2 is the same as that in FIG. 1.

When one of the bit lines in the sector 100 is selected, the column address and matrix row select signal MATY0 are applied to the global column decoder 700. Accordingly, the global column decoder 700 selects one (T1 for instance)of the pass transistors in the global column pass gate 500, thereby turning it on. Then, the data line D/L connected to the output line of the write driver 14 and the input line of the sense amplifier 12 is electrically connected to the global bit line (in this case, GBL0).

In addition, the local column decoder 7 receiving the column address and matrix row select signal MATX0 drives the Y-pass gate circuit 103 by the local column decoding signal, thereby turning on the NMOS transistor N1. Accordingly, one of the bit lines in the sector cell array 101 is electrically connected to the global bit line GBL0. By the read operation described above, data programmed by the memory cell transistor MC1 is, during a read operation, supplied to the input of the sense amplifier 12 connected to the data line through the bit line and global bit line. The data input to the sense amplifier 12 is read out through the output terminal of the sense amplifier 12.

As described above, if the plurality of the sectors are arranged in a B/L direction according to the hierarchical B/L structure, there is no need to add any additional sense amplifiers and write drivers for every sector in which a same matrix row select signal is used. As a result, in the plurality of sector cell arrays that are arranged in a column direction a well as in a row direction, data are sensed with only one sense amplifier and data are programmed with only one write driver.

While this invention has been particularly shown and described with references to preferred embodiments thereof, it will be understood by those skilled in the art that various changes in form and details may be made therein without departing from the spirit and scope of the invention as defined by the appended claims.

For instance, the hierarchical structure along a bit line direction can be applied to a nonvolatile memory device having a NAND or AND structure. Furthermore, the metal lines shown in FIG. 3 can be replaced with other conductive metal lines, or interchanged with each other.

What is claimed is:

1. A NOR type flash memory device performing an erase operation by a sector unit comprising:
a plurality of floating gate memory cells; and
a plurality of sectors for receiving a same matrix row select signal, bit lines of each of the sectors connected to global bit lines so that the plurality of sectors share a sense amplifier and a write driver.

2. The device of claim 1, wherein the global bit line is formed on a metal layer formed over the bit line and connected to the plurality of bit lines one by one, thereby having a hierarchical structure in a bit line direction relative to the sectors.

3. A NOR type flash memory device performing an erase operation by a sector unit, comprising:
a plurality of floating gate memory cells; and
a plurality of sectors for receiving matrix row select signals that are different from one another in a column direction and matrix column select signals that are different from one another in a row direction, word lines of each of the sectors being connected to global word lines and bit lines of each of the sectors being connected to global bit lines so that the plurality of sectors may share a sense amplifier and a write driver, the sectors being arranged in a matrix.

4. The device of claim 3, wherein the global word line is formed on a metal layer formed over the word line and connected to the plurality of word lines one by one through a local row decoder, thereby having a hierarchical structure in a word line direction relative to the sectors, and
the global bit line is formed on a metal layer formed over the bit line and connected to the plurality of bit lines one by one, thereby having the hierarchical structure in a bit line direction relative to the sectors.

5. A nonvolatile semiconductor device performing an erase operation by a sector unit and programming memory cells having a first or second logic states in response to input data having information of various bits, comprising a plurality of floating gate memory cells, the sectors each having a hierarchical structure in a word line direction as well as in a bit line direction so that the plurality of sectors may share a sense amplifier and a write driver, the sectors arranged in a row direction and a column direction.

6. The device of claim 5, wherein the device is a NOR type flash memory device.

7. A NOR type flash memory comprising:
a plurality of sector cell arrays comprising a plurality of memory cell transistors in which its gates each are connected to corresponding word lines of a plurality of word lines and its drains that do not share same word line are connected to corresponding bit lines of a plurality of bit lines;
row decoders for selecting the word lines;
a plurality of unit sectors arranged in a row matrix type and a column matrix type, each of the unit sectors comprising Y-pass gate circuits for selecting one of the bit lines in response to a local column decoding signal;
global row decoders and global column decoders arranged out of the sectors; and
a sense amplifier and a write driver commonly connected to output lines of global column pass gates;
wherein the plurality of bit lines are connected to a common output line through the Y-pass gate circuits and the global column pass gate so that the number of the sense amplifiers and write drivers can be reduced.

8. A flash memory storing data in a cell array having numerous word lines and bit lines by program or erase operation and performing a read operation by applying a predetermine voltage to selected word lines and bit lines, comprising:
a circuit for controlling word lines and bit lines in each of the sectors when the erase operation is performed in memory cells by a sector unit, the circuit having a hierarchical structure.

9. The device of claim 8, wherein the sectors each are deposited in a word line direction thereby forming a hierarchical structure of word lines, and deposited in a bit line direction thereby forming a hierarchical structure of bit lines

10. The device of claim 9, wherein selecting one of the sectors arranged parallel to the word line direction is performed by first generating a global word line enable signal and generating a word line enable signal in a sector cell array according to the signal, a matrix column select signal, and a row address.

11. The device of claim 9, wherein selecting one of the sectors arranged parallel to the bit line direction is performed by first generating a global bit line enable signal and generating a column decoding signal selecting a bit line enable signal in a sector cell array according to the signal, a matrix row select signal, and a column address.

12. A flash memory for storing data in a cell array having word lines and bit lines for performing program and erase operations and performing a read operation by application of a predetermined voltage to selected word lines and bit lines, the flash memory comprising global word lines and global word lines formed of second and third metal layers, respectively, the second and third metal layers being different from a first metal layer of bit lines of the cell array, the global word lines and global bit lines being coupled to a circuit for controlling the word lines and bit lines in each of a plurality of sectors of the cell array when the erase operation is performed in memory cells by sector unit, the circuit having a hierarchical structure.

13. A column decoding method of a NOR type flash memory device having a plurality of floating gate memory cells for performing an erase operation by sector unit, comprising performing a local column decoding operation and a global column decoding operation to hierarchically selected bit lines at a state that a plurality of sectors for receiving a same matrix row select signal in each of which bit lines are connected to global bit lines so that the plurality of sectors may share a sense amplifier and a write driver.
